(19) United States
(12) Patent Application Publication
(10) Pub. No.: US 2025/0081819 A1
(43) Pub. Date: Mar. 6, 2025

(54) DISPLAY PANEL AND METHOD FOR MANUFACTURING SAME, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Cheng ZENG, Beijing (CN); Jaeho LEE, Beijing (CN); Dongyu GAO, Beijing (CN); Dan WANG, Beijing (CN); Lulin MA, Beijing (CN); Zhenye WEI, Beijing (CN); Qiyun WANG, Beijing (CN); Xingjian CHENG, Beijing (CN)

(21) Appl. No.: 18/282,980

(22) PCT Filed: Dec. 21, 2022
(86) PCT No.: PCT/CN2022/140788

§ 371 Date: Sep. 19, 2023

(51) Int. Cl. H10K 59/80; H10K 59/12; H10K 59/122; H10K 59/38; H10K 102/00

(52) U.S. Cl. CPC H10K 59/8731; H10K 59/1201; H10K 59/122; H10K 59/38; H10K 2102/331; H10K 2102/351

(57) ABSTRACT

Provided is a display panel. The display panel includes: a base substrate, a plurality of light-emitting devices, a package layer, a hydrophobic layer, an isolation portion, and a light conversion structure; wherein the light-emitting devices are disposed on a side of the base substrate; the package layer is disposed on a side of the light-emitting devices and configured to package the light-emitting devices; the hydrophobic layer is disposed on a side of the package layer and in direct contact with the package layer; the isolation portion is disposed on a side of the hydrophobic layer, wherein a plurality of apertures are defined in the isolation portion; and the light conversion structure is disposed in the apertures and includes a transparent medium layer and a plurality of particles, and a face of the transparent medium layer is in direct contact with the hydrophobic layer.

### CROSS-REFERENCE TO RELATED APPLICATION

This application is a U.S. national stage of international application No. PCT/CN2022/140788, filed on Dec. 21, 2022, the disclosure of which is incorporated herein by reference in its entirety.

### TECHNICAL FIELD

The present disclosure relates to the field of display technologies, and in particular, relates to a display panel and a method for manufacturing the same, and a display device.

### BACKGROUND

With the development of the display technologies, requirements and application ranges of the display devices are increasing, and common display devices include mobile phones, televisions, tablet computers, laptop computers, and monitors.

### SUMMARY

Embodiments of the present disclosure provide a display panel and a method for manufacturing the same, and a display device. The technical solutions are as follows.

In some embodiments of the present disclosure, a display panel is provided. The display panel includes: a base substrate, a plurality of light-emitting devices, a package layer, a hydrophobic layer, an isolation portion, and a light conversion structure; wherein
the plurality of light-emitting devices are disposed on a side of the base substrate;
the package layer is disposed on a side, facing away from the base substrate, of the plurality of light-emitting devices, and the package layer is configured to package the plurality of light-emitting devices;
the hydrophobic layer is disposed on a side, facing away from the base substrate, of the package layer, and the hydrophobic layer is in direct contact with the package layer;
the isolation portion is disposed on a side, facing away from the base substrate, of the hydrophobic layer, wherein a plurality of apertures in one-to-one correspondence to the plurality of light-emitting devices are defined in the isolation portion, and an orthogonal projection of each of the plurality of apertures on the base substrate covers an orthogonal projection of the corresponding light-emitting device on the base substrate; and
the light conversion structure is disposed in the plurality of apertures, and the light conversion structure includes a transparent medium layer made of a hydrophobic material and a plurality of particles dispersed in the transparent medium layer, and a face, close to the base substrate, of the transparent medium layer is in direct contact with the hydrophobic layer.

In some embodiments, the hydrophobic layer is made of an organic material.

In some embodiments, the hydrophobic layer includes a hydrophobic layer body made of the organic material and a plurality of hollow particles dispersed in the hydrophobic layer body.

In some embodiments, the display panel further includes: a hydrophilic layer on a side, facing away from the base substrate, of the isolation portion, wherein at least part of the hydrophilic layer is disposed on sidewalls of the plurality of apertures, and a plurality of hollow grooves in one-to-one correspondence to the plurality of apertures are defined in the hydrophilic layer, wherein an orthogonal projection of each of the plurality of hollow grooves on the base substrate is within an orthogonal projection of the corresponding aperture on the base substrate.

In some embodiments, the hydrophilic layer includes a first portion covering the sidewalls of the plurality of apertures and a second portion covering the side, facing away from the base substrate, of the isolation portion.

In some embodiments, a shape of an orthogonal projection of the first portion on the base substrate is an annulus, and an inner boundary of the annulus is coincident with a boundary of the orthogonal projection of each of the plurality of hollow grooves on the base substrate.

In some embodiments, a refractive index of the hydrophobic layer is less than a refractive index of the light conversion structure.

In some embodiments, the package layer includes a first inorganic package layer, an organic package layer, and a second inorganic package layer that are laminated in a direction perpendicular to and away from the base substrate, wherein the hydrophobic layer is in direct contact with the second inorganic package layer, and a thickness of the hydrophobic layer is less than a thickness of the second inorganic package layer.

In some embodiments, the plurality of light-emitting devices are configured to emit blue light, and the display panel includes a red pixel sub-region, a green pixel sub-region, and a blue pixel sub-region; wherein
particles in the light conversion structure in the red pixel sub-region include red quantum dots for converting blue light to red light and scattering particles for scattering light;
particles in the light conversion structure in the green pixel sub-region include green quantum dots for converting blue light to green light and scattering particles for scattering light; and
particles in the light conversion structure in the blue pixel sub-region include scattering particles for scattering light.

In some embodiments, the display panel further includes: an auxiliary package layer on a side, facing away from the base substrate, of the light conversion structure and a color resist layer on a side, facing away from the base substrate, of the auxiliary package layer,
wherein the color resist layer includes a red color resist block in the red pixel sub-region, a green color resist block in the green pixel sub-region, a blue color resist block in the blue pixel sub-region, and a black matrix between two adjacent color resist blocks.

In some embodiments of the present disclosure, a display device is provided. The display device includes: a power supply assembly and a display panel electrically connected to the power supply assembly, wherein the display panel is the above display panel.

In some embodiments of the present disclosure, a method for manufacturing a display panel is provided. The method includes:
forming a plurality of light-emitting devices on a side of a base substrate;
forming a package layer on a side, facing away from the base substrate, of the plurality of light-emitting devices, wherein the package layer is configured to package the plurality of light-emitting devices;
forming a hydrophobic layer on a side, facing away from the base substrate, of the package layer, wherein the hydrophobic layer is in direct contact with the package layer;
forming an isolation portion on a side, facing away from the base substrate, of the hydrophobic layer, wherein a plurality of apertures in one-to-one correspondence to the plurality of light-emitting devices are defined in the isolation portion, wherein an orthogonal projection of each of the plurality of apertures on the base substrate covers an orthogonal projection of the corresponding light-emitting device on the base substrate; and
forming a light conversion structure in the plurality of apertures, wherein the light conversion structure includes a transparent medium layer made of a hydrophobic material and a plurality of particles dispersed in the transparent medium layer, and a face, close to the base substrate, of the transparent medium layer is in direct contact with the hydrophobic layer.

In some embodiments, prior to forming the light conversion structure in the plurality of apertures, the method further includes:
forming a hydrophilic layer on a side, facing away from the base substrate, of the isolation portion, wherein at least part of the hydrophilic layer is disposed on sidewalls of the plurality of apertures, and a plurality of hollow grooves in one-to-one correspondence to the plurality of apertures are defined in the hydrophilic layer, wherein an orthogonal projection of each of the plurality of hollow grooves on the base substrate is within an orthogonal projection of the corresponding aperture on the base substrate.

In some embodiments, upon forming the light conversion structure in the plurality of apertures, the method further includes:
forming an auxiliary package layer on a side, facing away from the base substrate, of the light conversion structure; and
forming a color resist layer on a side, facing away from the base substrate, of the auxiliary package layer.

In some embodiments, forming the light conversion structure in the plurality of apertures includes:
acquiring a mixed solution by mixing particles in a transparent solution made of the hydrophobic material; and
acquiring the light conversion structure by printing the mixed solution in the plurality of apertures by an inkjet printing process and curing the mixed solution in the plurality of apertures.

### BRIEF DESCRIPTION OF DRAWINGS

For clearer description of the technical solutions in the embodiments of the present disclosure. Apparently, the accompanying drawings in the following description show merely some embodiments of the present disclosure, and those of ordinary skill in the art may still derive other drawings from these accompanying drawings without any creative efforts.

FIG. 1 is a schematic diagram of a liquid on a surface of a solid;

FIG. 2 is a schematic diagram of another liquid on a surface of a solid;

FIG. 3 is a schematic diagram of a film structure of a currently normal display panel;

FIG. 4 is a schematic diagram of printing of a light conversion structure on a package layer;

FIG. 5 is a schematic diagram of a solution containing quantum dots on a second inorganic package layer;

FIG. 6 is a schematic diagram of a film structure of a display panel according to some embodiments of the present disclosure;

FIG. 7 is a schematic diagram of a hydrophobic solution on a hydrophobic layer according to some embodiments of the present disclosure;

FIG. 8 is a schematic diagram of a film structure of another display panel according to some embodiments of the present disclosure;

FIG. 9 is a schematic diagram of another hydrophobic solution on a hydrophobic layer according to some embodiments of the present disclosure;

FIG. 10 is a schematic diagram of a film structure of another display panel according to some embodiments of the present disclosure;

FIG. 11 is a schematic diagram of a film structure of another display panel according to some embodiments of the present disclosure;

FIG. 12 is a flowchart of a method for manufacturing a display panel according to some embodiments of the present disclosure; and

FIG. 13 is a flowchart of another method for manufacturing a display panel according to some embodiments of the present disclosure.

### DETAILED DESCRIPTION

To make the objectives, technical solutions, and advantages of the present disclosure clearer, the embodiments of the present disclosure are further described in detail hereinafter with reference to the accompanying drawings.

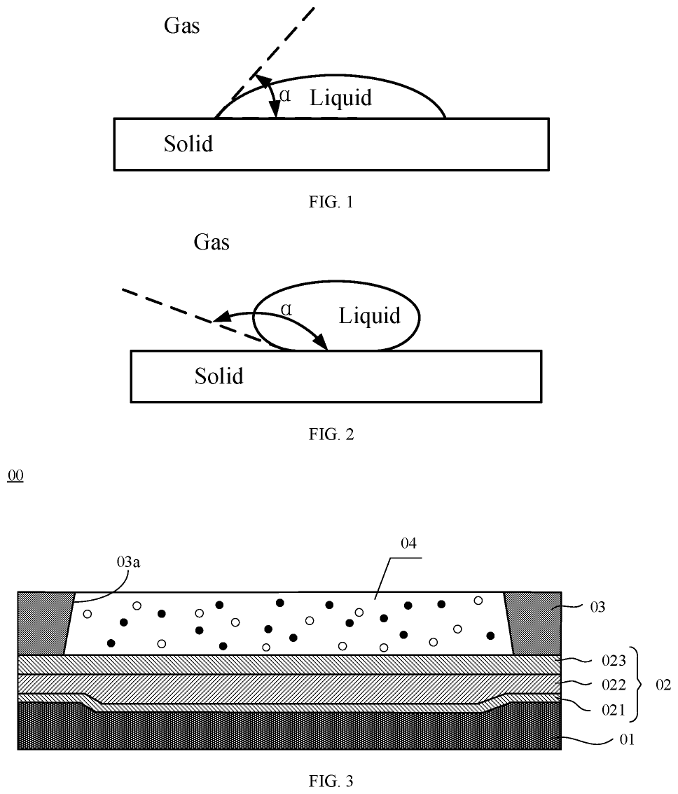

A contact angle of a liquid on a surface of a solid involved in the present disclosure is first described in the following embodiments. The contact angle of the liquid on the surface of the solid is used to indicate a wettability of the liquid on the surface of the solid, and the contact angle is an included angle between a tangent line of an interface of the gas and the liquid and a boundary of the solid and the liquid upon formation of a liquid drop of the liquid on the surface of the solid. As shown in FIG. 1, FIG. 1 is a schematic diagram of a liquid on a surface of a solid. In the case that the contact angle α of the liquid on the surface of the solid is less than 90°, the liquid is prone to wetting the surface of the solid. The less the contact angle α, the greater the ductility of the liquid on the surface of the solid, and the liquid is fully spread on the surface of the solid. As shown in FIG. 2, FIG. 2 is a schematic diagram of another liquid on a surface of a solid. In the case that the contact angle α of the liquid on the surface of the solid is greater than 90°, the liquid is difficult to wet the surface of the solid. The greater the contact angle α, the less the ductility of the liquid on the surface of the solid, and the liquid is difficult to be fully spread on the surface of the solid.

At present, quantum dot materials, as new light-emitting materials, are widely used in the display panel of the display device. Generally, the display panel includes a light-emitting substrate, and a quantum dot conversion layer on a light-emitting side of the light-emitting substrate. The quantum dot conversion layer is capable of converting light emitted by the light-emitting substrate to light of other colors. For example, the light-emitting substrate emits blue light, and the quantum dot conversion layer includes red quantum dots and green quantum dots. The red quantum dots convert the blue light emitted by the light-emitting substrate to red light, and the green quantum dots convert the blue light emitted by the light-emitting substrate to green light.

However, the quantum dot conversion layer in the display panel is formed by an inkjet printing process, and a uniformity of a thickness of the quantum dot conversion layer formed by the inkjet printing process is poor, such that the display panel has a poor display effect.

Referring to FIG. 3, FIG. 3 is a schematic diagram of a film structure of a currently normal display panel. The display panel 00 includes a light-emitting substrate 01, a package layer 02, an isolation portion 03, and a light conversion structure 04.

The light-emitting substrate 01 is provided with a plurality of light-emitting devices for emitting blue light. The package layer 02 is configured to package the light-emitting devices in the light-emitting substrate 01. The isolation portion 03 is disposed on a side, facing away from the light-emitting substrate 01, of the package layer 02, and a plurality of apertures 03a are defined in the isolation portion 03. The light conversion structure 04 is disposed in the plurality of apertures 03a and is in contact with the package layer 02.

Quantum dots are filled in the light conversion structure 04. That is, the light conversion structure 04 is a quantum dot conversion layer. The quantum dots in the light conversion structure 04 are capable of converting blue light from the light-emitting devices in the light-emitting substrate 01 to light of other colors. For example, quantum dots in the light conversion structure 04 in one part of the plurality of apertures 03a in the isolation portion 03 are capable of converting blue light to red light, and quantum dots in the light conversion structure 04 in the other part of the plurality of apertures 03a are capable of converting blue light to green light.

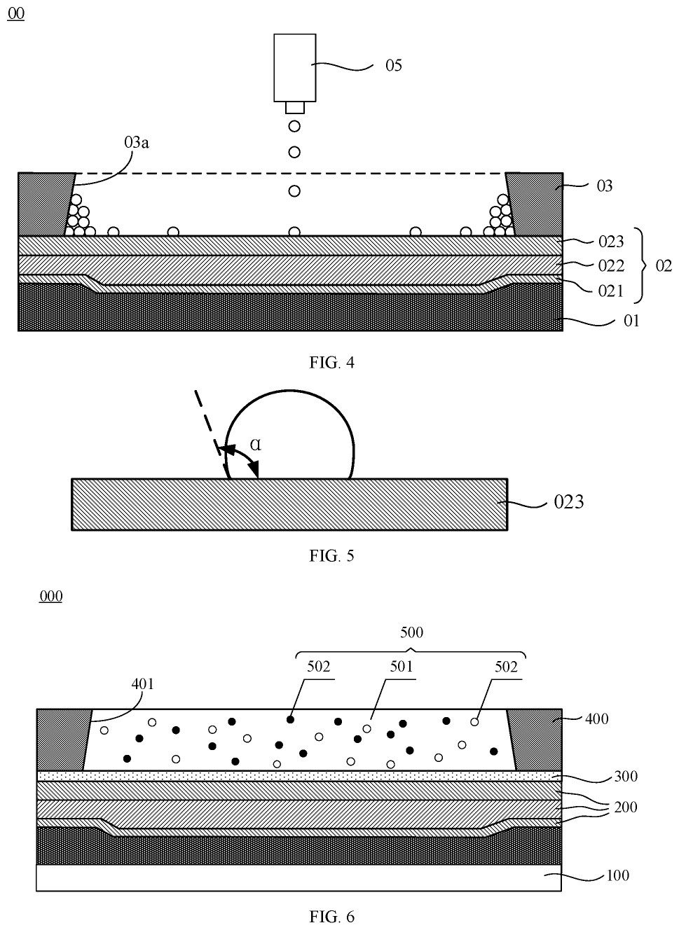

At present, the light conversion structure 04 in the display panel 00 generally requires to be formed by an inkjet printing process. For example, referring to FIG. 4, FIG. 4 is a schematic diagram of printing of a light conversion structure on a package layer. A solution containing quantum dots is printed in the aperture 03a in the isolation portion 03 by an inkjet printing head 05, and then the solution printed in the aperture 03a is cured to form the light conversion structure 04 in the aperture 03a.

However, the package layer 02 in the display panel 00 generally includes a first inorganic package layer 021, an organic package layer 022, and a second inorganic package layer 023 that are laminate. The second inorganic package layer 023 is in contact with the light conversion structure 04, and is made of an inorganic material that is generally hydrophilic. In the case that a hydrophobic solution is used in forming the light conversion structure 04 by the inkjet printing process, as shown in FIG. 5, FIG. 5 is a schematic diagram of a solution containing quantum dots on a second inorganic package layer, a contact angle α between the hydrophobic solution and a surface of the hydrophilic second inorganic package layer 023 is great, and generally ranges from 110° to 120°. Thus, the ductility of the solution containing quantum dots on the surface of the second inorganic package layer 023 is poor in forming the light conversion structure 04 by the inkjet printing process, and the solution containing quantum dots is difficult to be fully spread on the surface of the second inorganic package layer 023, such that the uniformity of the thickness of the solution containing quantum dots on the second inorganic package layer 023 is poor, and the uniformity of the thickness of the subsequently formed light conversion structure 04 is poor.

In addition, the isolation portion 03 is generally hydrophobic. In forming the light conversion structure 04 by the inkjet printing process, the hydrophobic isolation portion 03 absorbs the hydrophobic solution, such that the solution containing quantum dots converges at a position, close to the isolation portion 03, in the aperture 03a. Thus, the uniformity of the thickness of the subsequently formed light conversion structure 04 is more poor, and the poor phenomenon of the thinner center and the thicker two sides is caused.

In the case that the uniformity of the thickness of the light conversion structure 04 in the display panel is poor, the effect of converting light from the light-emitting substrate 01 to light of other colors by the light conversion structure 04 is poor, and the display effect of the display panel 00 is poor.

Referring to FIG. 6, FIG. 6 is a schematic diagram of a film structure of a display panel according to some embodiments of the present disclosure. The display panel 000 includes a base substrate 100, a plurality of light-emitting devices (not shown in FIG. 5), a package layer 200, a hydrophobic layer 300, an isolation portion 400, and a light conversion structure 500.

The plurality of light-emitting devices in the display panel 000 are disposed on a side of the base substrate 100. Illustratively, the light-emitting device is an organic light-emitting diode (OLED).

The package layer 200 in the display panel 000 is disposed on a side, facing away from the base substrate 100, of the plurality of light-emitting devices. The package layer 200 is configured to package the plurality of light-emitting devices. The package layer 200 is capable of isolating the light-emitting devices from the external environment, such that the moisture and oxygen in the external environment are prevented from corroding the light-emitting devices, and the usage lifetime of the light-emitting devices in the display panel is improved.

The hydrophobic layer 300 in the display panel 000 is disposed on a side, facing away from the base substrate 100, of the package layer 200. The hydrophobic layer 300 is in direct contact with the package layer 200.

The isolation portion 400 in the display panel 000 is disposed on a side, facing away from the base substrate 100, of the hydrophobic layer 300. A plurality of apertures 401 in the isolation portion 400 are in one-to-one correspondence to the plurality of light-emitting devices on the base substrate 100, and an orthogonal projection of each of the plurality of apertures 401 in the isolation portion 400 on the base substrate 100 covers an orthogonal projection of the corresponding light-emitting device on the base substrate 100.

The light conversion structure 500 in the display panel 000 is disposed in the plurality of apertures 401 in the isolation portion 400. The light conversion structure 500 is disposed in each aperture 401 in the isolation portion 400. As the orthogonal projection of each aperture 401 in the isolation portion 400 on the base substrate 100 covers a region of the corresponding light-emitting device, an orthogonal projection of the light conversion structure 500 in the aperture 401 on the base substrate 100 also covers the region of the corresponding light-emitting device. It should be noted that an area of the orthogonal projection of the light conversion structure 500 on the base substrate 100 is greater than or equal to an area of the region of the corresponding light-emitting device, such that light from the light-emitting devices in the display panel 000 is propagated by the light conversion structure 500 upon being converted by the light conversion structure 500 as much as possible, and the effect of converting the light from the light-emitting devices by the light conversion structure 500 is great.

In the embodiments of the present disclosure, the light conversion structure 500 in the display panel 000 includes a transparent medium layer 501 made of a hydrophobic material and a plurality of particles 502 dispersed in the transparent medium layer 501, and a face, close to the base substrate 100, of the transparent medium layer 501 is in direct contact with the hydrophobic layer 300. The particles 502 filled in the transparent medium layer 501 are quantum dots for converting the light from the light-emitting devices to light of other colors, or scattering particles for scattering light. In the case that the particles 502 in the light conversion structure 500 include quantum dots, the light conversion structure 500 is capable of converting light from the light-emitting devices to light of other colors. In the case that the particles 502 in the light conversion structure 500 include scattering particles, the light conversion structure 500 is capable of scattering light from the light-emitting devices, such that a view angle of the display panel 000 is great.

In the present disclosure, the light conversion structure 500 in the display panel 000 is formed by the inkjet printing process. Illustratively, upon formation of the isolation portion 400 in the display panel 000, the solution containing the particles 502 is printed in the aperture 401 in the isolation portion 400 by inkjet printing, and the solution printed in the aperture 401 is then cured, such that the light conversion structure 500 is formed in the aperture 401. The solution is a hydrophobic solution.

As the solution printed in the aperture 401 contains a plurality of particles 502, the transparent medium layer 501 in the light conversion structure 500 and a plurality of particles 502 dispersed in the transparent medium layer 501 are formed by curing the solution printed in the aperture 401.

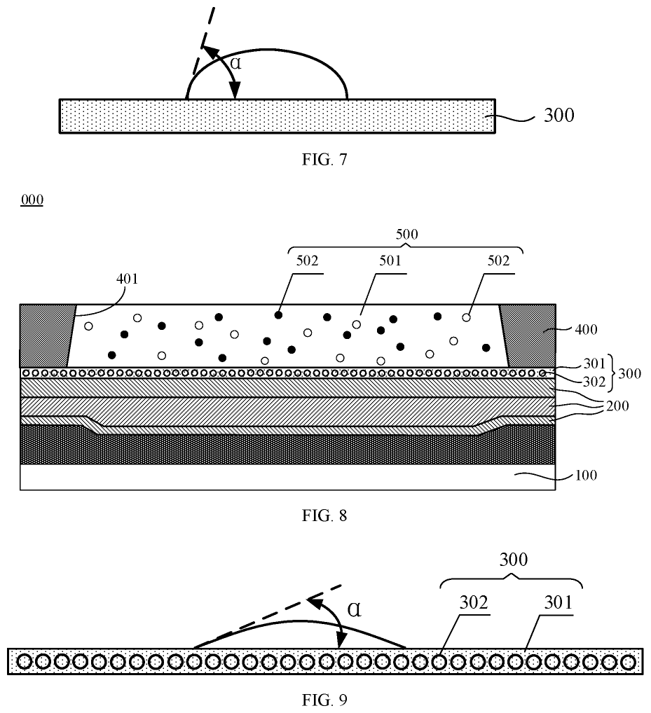

In this case, as the hydrophobic layer 300 is disposed on the side, facing away from the base substrate 100, of the package layer 200, and the hydrophobic layer 300 is hydrophobic, as shown in FIG. 7, FIG. 7 is a schematic diagram of a hydrophobic solution on a hydrophobic layer according to some embodiments of the present disclosure, the hydrophobic solution is in direct contact with the hydrophobic layer 300 in forming the light conversion structure 500 by the inkjet printing process, such that a contact angle α between a hydrophobic solution and the hydrophobic layer 300 is less. Illustratively, the contact angle between the hydrophobic solution and the hydrophobic layer 300 is less than or equal to 60°. Thus, in forming the light conversion structure 500 by the inkjet printing process, the ductility of the solution containing particles 502 on the surface of the hydrophobic layer is great, and the solution containing particles 502 is fully spread on the surface of the hydrophobic layer 300, such that a thickness of the solution containing particles 502 on the hydrophobic layer 300 is uniform, and a thickness of the light conversion structure formed by curing is also uniform. As such, an effect of converting light from the light-emitting device to light of other colors by the light conversion structure 500 is great, an effect of scattering the light from the light-emitting device is great, and a display effect of the display panel 000 is efficiently improved.

In summary, the display panel in the embodiments of the present disclosure includes: a base substrate, a plurality of light-emitting devices, a hydrophobic layer, an isolation portion, and a light conversion structure. As the hydrophobic layer is disposed on a side, facing away from the base substrate, of the package layer, the hydrophobic layer is hydrophobic, and a solution mixed with particles in forming the light conversion structure by an inkjet printing process is a hydrophobic solution, the hydrophobic solution is in direct contact with the hydrophobic layer, such that a contact angle between a hydrophobic solution and the hydrophobic layer is less. Thus, in forming the light conversion structure by the inkjet printing process, the ductility of the solution mixed with particles on the surface of the hydrophobic layer is great, and the solution mixed with particles is fully spread on the surface of the hydrophobic layer, such that a thickness of the solution mixed with particles on the hydrophobic layer is uniform, and a thickness of the light conversion structure formed by curing is also uniform. As such, an effect of converting light from the light-emitting device to light of other colors by the light conversion structure is great, an effect of scattering the light from the light-emitting device is great, and a display effect of the display panel is efficiently improved.

In the embodiments of the present disclosure, as shown in FIG. 6, the hydrophobic layer 300 in the display panel 000 is of a single-layer structure. The hydrophobic layer 300 is made of an organic material. For example, the organic material includes one or more of an acrylic resin, a polyurethane resin, a silicone resin, an epoxy resin, and the like. In the present disclosure, as the organic material is generally hydrophobic, the hydrophobic layer 300 in the display panel 000 is made of the organic material.

Furthermore, as shown in FIG. 8, FIG. 8 is a schematic diagram of a film structure of another display panel according to some embodiments of the present disclosure. The hydrophobic layer 300 in the display panel 000 includes a hydrophobic layer body 301 made of the organic material and a plurality of hollow particles 302 dispersed in the hydrophobic layer body 301.

The organic material includes one or more of an acrylic resin, a polyurethane resin, a silicone resin, an epoxy resin, and the like. In the present disclosure, as the organic material is generally hydrophobic, a surface of the hydrophobic layer body 301 is hydrophobic in the case that the hydrophobic layer body 301 in the hydrophobic layer 300 is made of the organic material.

The hollow particles 302 in the hydrophobic layer 300 are in hollow spheres, and the hollow particles 302 are made of one or more of silicon oxide, aluminum oxide, and calcium oxide.

It should be noted that a calculation formula of an actual contact angle of a liquid on a surface of a solid is:

cos α*=r cos α.

α* represents an actual contact angle of a liquid on a surface of a solid, r represents a roughness of a surface of a solid, and a represents a contact angle of a liquid on a surface of a smooth solid. The roughness of a surface of a solid indicates a ratio of an area of the surface of the solid to an area of an orthogonal projection of the surface of the solid on a plane. The ratio is generally greater than 1. The greater the ration, the greater the roughness of the surface of the solid.

In this case, the roughness of the surface of the hydrophobic layer body 301 is ensured to be great by disposing the hollow particles 302 in the hydrophobic layer body 301. As such, in forming the light conversion structure 500 by the inkjet printing process, as shown in FIG. 9, FIG. 9 is a schematic diagram of another hydrophobic solution on a hydrophobic layer according to some embodiments of the present disclosure, a contact angle α between the hydrophobic solution and the hydrophobic layer body 301 is further reduced upon printing of the hydrophobic solution on a surface of the hydrophobic layer body 301 in the hydrophobic layer 300. Illustratively, the contact angle α between the hydrophobic solution and the hydrophobic layer body 301 ranges from 20° to 30°. Thus, upon printing of the hydrophobic solution on the surface of the hydrophobic layer body 301, the ductility of the hydrophobic solution on the surface of the hydrophobic layer body 301 is further improved, and the uniformity of the thickness of the light conversion structure 500 formed by curing is further improved.

In the embodiments of the present disclosure, in the display panel 000, a refractive index of the hydrophobic layer 300 is less than a refractive index of the light conversion structure 500. As such, in the case that the light from the light-emitting devices runs through the light conversion structure 500, part of the light is reflected to the base substrate 100 by the particles 502 in the light conversion structure 500. In the case that the refractive index of the hydrophobic layer 300 is less than the refractive index of the light conversion structure 500, light reflected by the particles 502 and irradiated to the base substrate 100 is prone to the total reflection on an interface between the hydrophobic layer 300 and the light conversion structure 500, such that the light is reflected to the light conversion structure 500 based on the total reflection, a luminous efficiency of the display panel 100 is efficiently improved, and a converting efficiency of quantum dots in the light conversion structure 500 to light is improved. As such, the display effect of the display panel 000 is further improved.

It should be noted that for the hydrophobic layer 300 not disposed with the hollow particles, the refractive index of the hydrophobic layer 300 in the display panel 000 ranges from 1.4 to 1.6. For the hydrophobic layer 300 disposed with the hollow particles 302, as the hydrophobic layer 300 is disposed with the hollow particles, the hollow particles 302 are in hollow spheres and generally filled with air, and a refractive index of the air is less, the refractive index of the hydrophobic layer 300 disposed with the hollow particles 302 ranges from 1.30 to 1.45.

It should be further noted that in the display panel 000, the refractive index of the hydrophobic layer 300 is less than a refractive index of the package layer 200. As light from the light-emitting devices in the display panel 000 in the present disclosure is of shorter wavelength and is blue light, the light from the light-emitting devices is not prone to the total reflection on the interface between the hydrophobic layer 300 and the package layer 200, such that the light from the light-emitting devices runs through the package layer 200 and the hydrophobic layer 300, and is then reflected to the light conversion structure 500.

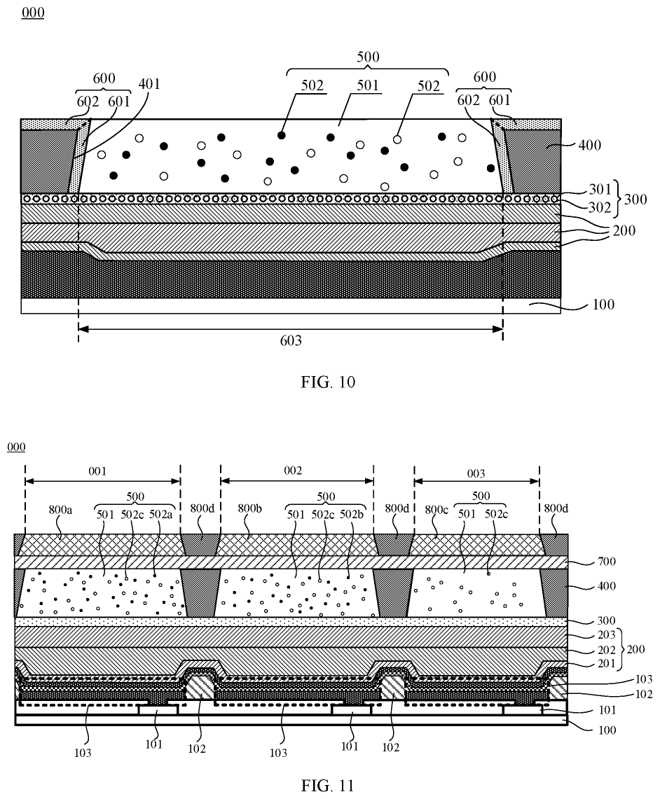

In the embodiments of the present disclosure, referring to FIG. 10, FIG. 10 is a schematic diagram of a film structure of another display panel according to some embodiments of the present disclosure. The display panel 000 further includes a hydrophilic layer 600 on a side, facing away from the base substrate 100, of the isolation portion 400. At least part of the hydrophilic layer 600 is disposed on sidewalls of the plurality of apertures 401 in the isolation portion 400. As the hydrophilic layer 600 is hydrophilic, in forming the light conversion structure 500 by the inkjet printing process, a portion of the hydrophilic layer 600 on the sidewalls of the plurality of apertures 401 repels the hydrophobic solution. As such, even the isolation portion 400 in the display panel 000 is hydrophobic, the hydrophobic solution printed in the apertures 401 in the isolation portion 400 is not converged at the position close to the isolation portion 400 under the action of the hydrophilic layer 600 on the sidewalls of the apertures 401, and the uniformity of the thickness of the subsequently formed light conversion structure 500 is further improved.

Illustratively, the thickness of the hydrophilic layer 600 in the display panel 000 ranges from 0.5 μm to 1 μm, and a material of the hydrophilic layer 600 is one or more of silicon nitride, silicon oxynitride, silicon oxide, aluminum oxide, barium oxide, and calcium oxide. In some embodiments, the material of the hydrophilic layer 600 is other hydrophilic materials, which is not limited in the embodiments of the present disclosure.

A plurality of hollow grooves 603 in one-to-one correspondence to the plurality of apertures 401 in the isolation portion 400 are defined in the hydrophilic layer 600. An orthogonal projection of each of the plurality of hollow grooves 603 in the hydrophilic layer 600 on the base substrate 100 is within an orthogonal projection of the corresponding aperture 401 on the base substrate 100. As such, in forming the light conversion structure 500 by the inkjet printing process, the hydrophobic solution is in contact with the hydrophobic layer 300 upon running through the hollow grooves 603 in the hydrophilic layer 600, such that the uniformity of the thickness of the hydrophobic solution printed in the apertures 401 is great.

In some embodiments, the hydrophilic layer 600 in the display panel 000 includes a first portion 601 covering the sidewalls of the plurality of apertures 401 in the isolation portion 400 and a second portion 602 covering the side, facing away from the base substrate 100, of the isolation portion 400.

In this case, in forming the hydrophilic layer 600, upon disposing of a complete layer of a hydrophilic thin film on the side, facing away from the base substrate 100, of the isolation portion 400, only a portion of the hydrophilic thin film in the aperture 401 requires to be removed in forming the hydrophilic layer 600 by performing the one patterning process on the hydrophilic thin film, such that the hollow grooves 603 in the hydrophilic layer 600 are formed in the aperture 401 without removing the portion of the hydrophilic thin film in the isolation portion 400, and the manufacturing process of the hydrophilic layer 600 is simplified. In addition, in the case that the first portion 601 in the hydrophilic layer 600 covers the sidewall of the aperture 401 in the isolation portion 400, the hydrophobic solution is not in contact with the isolation portion 400 in forming the light conversion structure 500 by the inkjet printing process, such that the hydrophobic solution is not converged by the isolation portion 400.

In the present disclosure, as the first portion 601 in the hydrophilic layer 600 covers the sidewall of the aperture 401, and the sidewall of the aperture 401 generally tilts towards a face, facing away from the base substrate 100, of the hydrophobic layer 300, a shape of an orthogonal projection of the first portion 601 in the hydrophilic layer 600 on the base substrate 100 is an annulus, and an inner boundary of the orthogonal projection of the first portion 601 on the base substrate 100 is coincident with a boundary of the orthogonal projection of the hollow groove 603 on the base substrate 100. In this case, a bottom of the hydrophobic solution printed in the aperture 401 is only in contact with the surface of the hydrophobic layer 300 and is not in contact with the surface of the hydrophilic layer 600 in forming the light conversion structure 500 by the inkjet printing process, such that the uniformity of the thickness of the hydrophobic solution printed in the aperture 401 is further improved.

In some embodiments, as shown in FIG. 11, FIG. 11 is a schematic diagram of a film structure of another display panel according to some embodiments of the present disclosure. The package layer 200 in the display panel 000 includes a first inorganic package layer 201, an organic package layer 202, and a second inorganic package layer 203 that are laminated in a direction perpendicular to and away from the base substrate 100. The hydrophobic layer 300 in the display panel 000 is disposed on the side, facing away from the base substrate 100, of the second inorganic package layer 203, and is in contact with the second inorganic package layer 203.

The hydrophobic layer 300 in the display panel 000 is configured to change properties of a surface of the second inorganic package layer 203, such that the uniformity of the thickness of the hydrophobic solution printed on the hydrophobic layer 300 is great. As the hydrophobic layer 300 does not require to package the light-emitting devices in the display panel 000, the thickness of the hydrophobic layer 300 is not too thick and is less than a thickness of the second inorganic package layer 203. Illustratively, the thickness of the hydrophobic layer 300 ranges from 0.2 μm to 0.5 μm, and thus the thinner hydrophobic layer 300 does not affect the overall thickness of the display panel 000.

In the embodiments of the present disclosure, referring to FIG. 11, the display panel 000 further includes a plurality of pixel drive circuits 101 electrically connected to the plurality of light-emitting devices 103 in one-to-one correspondence and a pixel define layer 102 on a side, close to the base substrate 100, of the package layer 200. Each pixel drive circuit 101 is configured to drive the corresponding light-emitting device 103 to emit light, and the plurality of pixel drive circuits 101 are closer to the base substrate 100 than the plurality of light-emitting devices 103. The pixel define layer 102 is configured to define a plurality of pixel sub-regions on a side of the base substrate 100. The plurality of pixel sub-regions are in one-to-one correspondence to the plurality of light-emitting devices 103, and each light-emitting device 103 is disposed in the corresponding pixel sub-region.

In some embodiments, the light-emitting devices 103 in the display panel 000 are configured to emit blue light, and the plurality of pixel sub-regions in the display panel 000 are divided to a plurality of red pixel sub-regions 001, a plurality of green pixel sub-regions 002, and a plurality of blue pixel sub-regions 003.

Particles in the light conversion structure 500 in the red pixel sub-regions 001 include red quantum dots 502a for converting blue light to red light and scattering particles 502a for scattering light. In the red pixel sub-regions 001, blue light from the light-emitting devices 103 are converted to red light by the red quantum dots 502a upon being irradiated to the light conversion structure 500, and the blue light and the red light are scattered by the scattering particles 502a, such that much blue light is converted to the red light by the red quantum dots 502a, the outgoing angle of the converted red light is great, and the view angle of the display panel 000 is great.

Particles in the light conversion structure 500 in the green pixel sub-regions 002 include green quantum dots 502b for converting blue light to green light and scattering particles 502b for scattering light. In the green pixel sub-regions 002, blue light from the light-emitting devices 103 are converted to green light by the green quantum dots 502b upon being irradiated to the light conversion structure 500, and the blue light and the green light are scattered by the scattering particles 502b, such that much blue light is converted to the green light by the green quantum dots 502b, the outgoing angle of the converted green light is great, and the view angle of the display panel 000 is great.

Particles in the light conversion structure 500 in the blue pixel sub-regions 003 include scattering particles 502c for scattering light. In the blue pixel sub-regions 003, blue light from the light-emitting devices 103 are scattered by the scattering particles 502c upon being irradiated to the light conversion structure 500, such that the outgoing angle of the blue light is great, and the view angle of the display panel 000 is great.

As such, blue light from the light-emitting devices 103 in the red pixel sub-region 001 is converted to red light by the light conversion structure 500 in the red pixel sub-region 001, and then the red light is emitted. Blue light from the light-emitting devices 103 in the green pixel sub-region 002 is converted to green light by the light conversion structure 500 in the green pixel sub-region 002, and then the green light is emitted. Blue light from the light-emitting devices 103 in the blue pixel sub-region 003 is still the blue light upon running through the light conversion structure 500 in the blue pixel sub-region 003. Thus, the pixel sub-regions in the display panel emit light of the corresponding colors, such that the display panel 000 displays color screens.

Furthermore, the display panel 000 further includes an auxiliary package layer 700 on a side, facing away from the base substrate 100, of the light conversion structure 500 and a color resist layer 800 on a side, facing away from the base substrate 100, of the auxiliary package layer 700. The auxiliary package layer 700 is configured to package the light conversion structure 500 in the display panel 000, and the light conversion structure 500 is not corroded by the moisture and oxygen in the external environment by the auxiliary package layer 700.

The color resist layer 800 in the display panel 000 includes a red color resist block 800a in the red pixel sub-region 001, a green color resist block 800b in the green pixel sub-region 002, a blue color resist block 800c in the blue pixel sub-region 003, and a black matrix 800d between two adjacent color resist blocks.

The red color resist block 800a is capable of filtering light of other colors than red, such that the red pixel sub-region 001 emits pure red light. The green color resist block 800b is capable of filtering light of other colors than green, such that the green pixel sub-region 002 emits pure green light. The blue color resist block 800c is capable of filtering light of other colors than blue, such that the blue pixel sub-region 003 emits pure blue light. The black matrix 800d between two adjacent color resist blocks in the color resist layer 800 is capable of absorbing light from a side face of the color resist block. For example, the black matrix 800d is capable of absorbing red light from a side face of the red color resist block 800a, such that the red light is not irradiated to the adjacent green pixel sub-region 002 and the adjacent blue pixel sub-region 003. As such, the poor phenomenon of the cross color of the display panel 000 is efficiently avoided by the black matrix 800d.

In summary, the display panel in the embodiments of the present disclosure includes: a base substrate, a plurality of light-emitting devices, a hydrophobic layer, an isolation portion, and a light conversion structure. As the hydrophobic layer is disposed on a side, facing away from the base substrate, of the package layer, the hydrophobic layer is hydrophobic, and a solution mixed with particles in forming the light conversion structure by an inkjet printing process is a hydrophobic solution, the hydrophobic solution is in direct contact with the hydrophobic layer, such that a contact angle between a hydrophobic solution and the hydrophobic layer is less. Thus, in forming the light conversion structure by the inkjet printing process, the ductility of the solution mixed with particles on the surface of the hydrophobic layer is great, and the solution mixed with particles is fully spread on the surface of the hydrophobic layer, such that a thickness of the solution mixed with particles on the hydrophobic layer is uniform, and a thickness of the light conversion structure formed by curing is also uniform. As such, an effect of converting light from the light-emitting device to light of other colors by the light conversion structure is great, an effect of scattering the light from the light-emitting device is great, and a display effect of the display panel is efficiently improved.

Embodiments of the present disclosure further provide a display device. The display device is a product or a component with a display function, such as a mobile phone, a tablet computer, a television, a display, a notebook computer, a digital photo frame, a navigator, and the like. The display device further includes a power supply assembly and a display panel electrically connected to the power supply assembly. The display panel is a display panel in the above embodiments, for example, the display panel shown in FIG. 6, FIG. 8, FIG. 10, or FIG. 11.

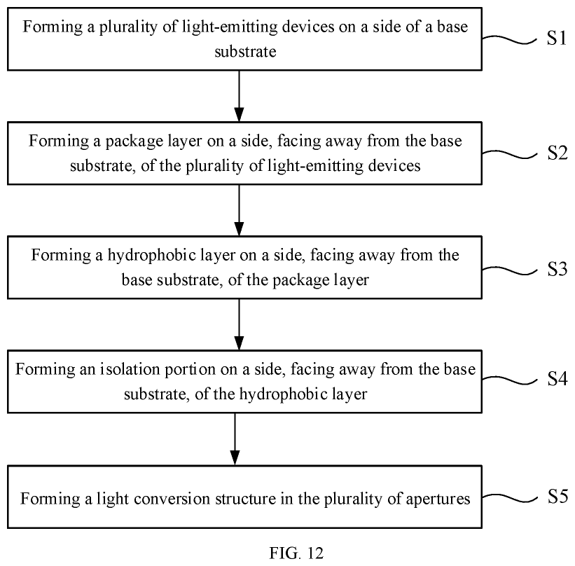

Referring to FIG. 12, FIG. 12 is a flowchart of a method for manufacturing a display panel according to some embodiments of the present disclosure. The embodiments of the present disclosure provide a method for manufacturing a display panel, and the method for manufacturing the display panel is applicable to manufacturing the display panel in FIG. 6. The method for manufacturing the display panel includes the following processes.

In S1, a plurality of light-emitting devices are formed on a side of a base substrate.

In S2, a package layer is formed on a side, facing away from the base substrate, of the plurality of light-emitting devices, wherein the package layer is configured to package the plurality of light-emitting devices.

In S3, a hydrophobic layer is formed on a side, facing away from the base substrate, of the package layer, wherein the hydrophobic layer is in direct contact with the package layer.

In S4, an isolation portion is formed on a side, facing away from the base substrate, of the hydrophobic layer, wherein a plurality of apertures in one-to-one correspondence to the plurality of light-emitting devices are defined in the isolation portion, wherein an orthogonal projection of each of the plurality of apertures on the base substrate covers an orthogonal projection of the corresponding light-emitting device on the base substrate.

In S5, a light conversion structure is formed in the plurality of apertures, wherein the light conversion structure includes a transparent medium layer made of a hydrophobic material and a plurality of particles dispersed in the transparent medium layer, and a face, close to the base substrate, of the transparent medium layer is in direct contact with the hydrophobic layer.

In summary, in the method for manufacturing the display panel in the embodiments of the present disclosure, as the hydrophobic layer is disposed on a side, facing away from the base substrate, of the package layer, the hydrophobic layer is hydrophobic, and a solution mixed with particles in forming the light conversion structure by an inkjet printing process is a hydrophobic solution, the hydrophobic solution is in direct contact with the hydrophobic layer, such that a contact angle between a hydrophobic solution and the hydrophobic layer is less. Thus, in forming the light conversion structure by the inkjet printing process, the ductility of the solution mixed with particles on the surface of the hydrophobic layer is great, and the solution mixed with particles is fully spread on the surface of the hydrophobic layer, such that a thickness of the solution mixed with particles on the hydrophobic layer is uniform, and a thickness of the light conversion structure formed by curing is also uniform. As such, an effect of converting light from the light-emitting device to light of other colors by the light conversion structure is great, an effect of scattering the light from the light-emitting device is great, and a display effect of the display panel is efficiently improved.

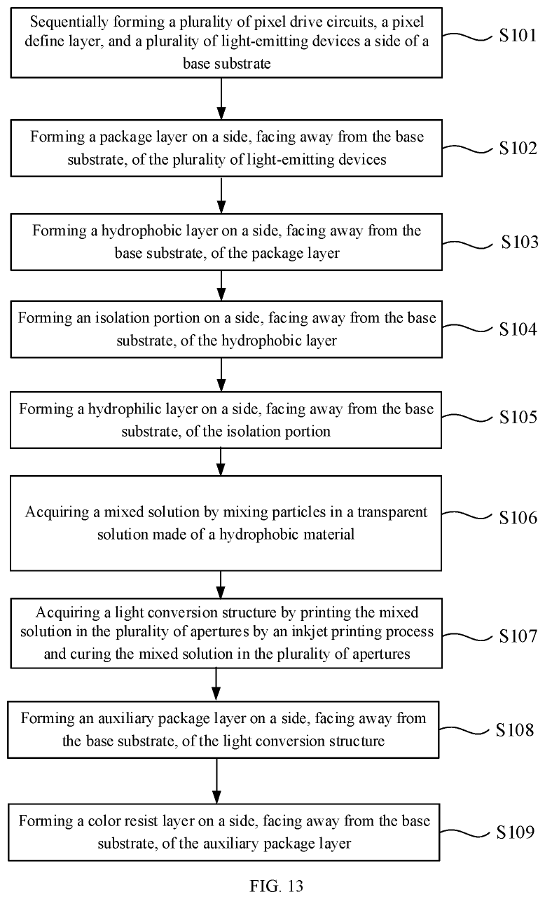

Referring to FIG. 13, FIG. 13 is a flowchart of another method for manufacturing a display panel according to some embodiments of the present disclosure. The method for manufacturing the display panel is applicable to manufacturing the display panel in FIG. 6, FIG. 8, FIG. 10, or FIG. 11. The method for manufacturing the display panel includes the following processes.

In S101, a plurality of pixel drive circuits, a pixel define layer, and a plurality of light-emitting devices are sequentially formed on a side of the base substrate.

Structures of the plurality of pixel drive circuits, the pixel define layer, and the plurality of light-emitting devices sequentially formed on the side of the base substrate are referred to corresponding structures in the display panel shown in FIG. 11, which are not repeated herein.

In S102, a package layer is formed on a side, facing away from the base substrate, of the plurality of light-emitting devices.

The structure of the package layer is referred to the corresponding structure in the display panel shown in FIG. 11, which is not repeated herein.

In S103, a hydrophobic layer is formed on a side, facing away from the base substrate, of the package layer.

The hydrophobic layer is made of one or more of an acrylic resin, a polyurethane resin, a silicone resin, an epoxy resin, and the like. A thickness of the hydrophobic layer ranges from 0.2 μm to 0.5 μm. The hydrophobic layer is or is not filled with hollow particles, which is not limited in the embodiments of the present disclosure.

Illustratively, the hydrophobic layer is formed on the side, facing away from the base substrate, of the package layer by any one of depositing, coating, sputtering, and the like, and the hydrophobic layer is in direct contact with the package layer.

In S104, an isolation portion is formed on a side, facing away from the base substrate, of the hydrophobic layer.

An isolation portion thin film is formed on the side, facing away from the base substrate, of the hydrophobic layer by any one of depositing, coating, sputtering, and the like. Then, the isolation portion is formed by performing a one patterning process on the isolation portion thin film. A plurality of apertures in one-to-one correspondence to the plurality of light-emitting devices are defined in the isolation portion, and an orthogonal projection of each of the plurality of apertures on the base substrate covers an orthogonal projection of the corresponding light-emitting device on the base substrate.

In S105, a hydrophilic layer is formed on a side, facing away from the base substrate, of the isolation portion.

In some embodiments, a material of the hydrophilic layer is one or more of silicon nitride, silicon oxynitride, silicon oxide, aluminum oxide, barium oxide, and calcium oxide, and a thickness of the hydrophilic layer ranges from 0.5 μm to 1 μm.

Illustratively, a hydrophilic thin film is formed on the side, facing away from the base substrate, of the isolation portion by any one of depositing, coating, sputtering, and the like. Then, the hydrophilic layer is formed by performing a one patterning process on the hydrophilic thin film. A plurality of hollow grooves in one-to-one correspondence to the plurality of apertures are defined in the hydrophilic layer. An orthogonal projection of each hollow groove on the base substrate is within an orthogonal projection of the corresponding aperture on the base substrate.

In S106, a mixed solution is acquired by mixing particles in a transparent solution made of a hydrophobic material.

Illustratively, the transparent solution is mixed with red quantum dots and scattering particles, green quantum dots and scattering particles, or only scattering particles.

In S107, a light conversion structure is acquired by printing the mixed solution in the plurality of apertures by an inkjet printing process and curing the mixed solution in the plurality of apertures.

Illustratively, as the display panel includes a red pixel sub-region, a green pixel sub-region, and a blue pixel sub-region, and light conversion structures printed in different pixel sub-regions of different colors are different, a solution mixed with red quantum dots and scattering particles is printed in the apertures in the red pixel sub-region by an inkjet printing head to acquire the light conversion structure in the red pixel sub-region, a solution mixed with green quantum dots and scattering particles is printed in the apertures in the green pixel sub-region by the inkjet printing head to acquire the light conversion structure in the green pixel sub-region, and a solution mixed with scattering particles is printed in the apertures in the blue pixel sub-region by the inkjet printing head to acquire the light conversion structure in the blue pixel sub-region. Then, the solutions mixed with the particles in the apertures are cured together to acquire the light conversion structures in different pixel sub-regions of different colors. The acquired light conversion structures include a transparent medium layer made of a hydrophilic material and a plurality of particles dispersed in the transparent medium layer, and a face, close to the base substrate, of the transparent medium layer is in direct contact with the hydrophilic layer.

In S108, an auxiliary package layer is formed on a side, facing away from the base substrate, of the light conversion structure.

In S109, a color resist layer is formed on a side, facing away from the base substrate, of the auxiliary package layer.

Illustratively, the structures of the auxiliary package layer and the color resist layer are referred to corresponding structures in the display panel shown in FIG. 11, which are not repeated herein.

It should be noted that the one patterning process in the above embodiments includes photoresist coating, exposing, developing, etching, and photoresist removing. In addition, the principles of manufacturing the display panel in the above embodiments are referred to the above embodiments of the structure of the display panel, which are not repeated herein.

It should be noted that, the order of the processes of the method for manufacturing the display panel provided in the embodiments of the present disclosure may be appropriately adjusted, and the processes may also be removed or added as required. Any variations to the methods readily derived by persons skilled in the art within the technical scope disclosed in the present disclosure shall fall within the protection scope of the present disclosure. Therefore, details are not described herein again.

In summary, in the method for manufacturing the display panel in the embodiments of the present disclosure, as the hydrophobic layer is disposed on a side, facing away from the base substrate, of the package layer, the hydrophobic layer is hydrophobic, and a solution mixed with particles in forming the light conversion structure by an inkjet printing process is a hydrophobic solution, the hydrophobic solution is in direct contact with the hydrophobic layer, such that a contact angle between a hydrophobic solution and the hydrophobic layer is less. Thus, in forming the light conversion structure by the inkjet printing process, the ductility of the solution mixed with particles on the surface of the hydrophobic layer is great, and the solution mixed with particles is fully spread on the surface of the hydrophobic layer, such that a thickness of the solution mixed with particles on the hydrophobic layer is uniform, and a thickness of the light conversion structure formed by curing is also uniform. As such, an effect of converting light from the light-emitting device to light of other colors by the light conversion structure is great, an effect of scattering the light from the light-emitting device is great, and a display effect of the display panel is efficiently improved.

It should be noted that in the accompanying drawings, for clarity of the illustration, the dimension of the layers and regions may be scaled up. It should be understood that when an element or layer is described as being “on” another element or layer, the described element or layer may be directly located on other elements or layers, or an intermediate layer may exist. In addition, it should be understood that when an element or layer is described as being “under” another element or layer, the described element or layer may be directly located under other elements, or more than one intermediate layer or element may exist. In addition, it should be further understood that when a layer or element is described as being arranged “between” two layers or elements, the described layer or element may be the only layer between the two layers or elements, or more than one intermediate layer or element may exist. In the whole disclosure, like reference numerals indicate like elements.

In the present disclosure, the terms “first” and “second” are only used for the purpose of description and should not be construed as indicating or implying relative importance or implicitly indicating the number of technical features as indicated. Unless otherwise clearly defined, the expression “a plurality of” refers to two or more.

Described above are example embodiments of the present disclosure, and are not intended to limit the present disclosure. Any modifications, equivalent replacements, improvements and the like made within the spirit and principles of the present disclosure should be included within the scope of protection of the present disclosure.

1. A display panel, comprising: a base substrate, a plurality of light-emitting devices, a package layer, a hydrophobic layer, an isolation portion, and a light conversion structure; wherein
the plurality of light-emitting devices are disposed on a side of the base substrate;
the package layer is disposed on a side, facing away from the base substrate, of the plurality of light-emitting devices, and the package layer is configured to package the plurality of light-emitting devices;
the hydrophobic layer is disposed on a side, facing away from the base substrate, of the package layer, and the hydrophobic layer is in direct contact with the package layer;
the isolation portion is disposed on a side, facing away from the base substrate, of the hydrophobic layer, wherein a plurality of apertures in one-to-one correspondence to the plurality of light-emitting devices are defined in the isolation portion, and an orthogonal projection of each of the plurality of apertures on the base substrate covers an orthogonal projection of the corresponding light-emitting device on the base substrate; and
the light conversion structure is disposed in the plurality of apertures, and the light conversion structure comprises a transparent medium layer made of a hydrophobic material and a plurality of particles dispersed in the transparent medium layer, and a face, close to the base substrate, of the transparent medium layer is in direct contact with the hydrophobic layer.

2. The display panel according to claim 1, wherein the hydrophobic layer is made of an organic material.

3. The display panel according to claim 2, wherein the hydrophobic layer comprises a hydrophobic layer body made of the organic material and a plurality of hollow particles dispersed in the hydrophobic layer body.

4. The display panel according to claim 1, further comprising: a hydrophilic layer on a side, facing away from the base substrate, of the isolation portion, wherein at least part of the hydrophilic layer is disposed on sidewalls of the plurality of apertures, and a plurality of hollow grooves in one-to-one correspondence to the plurality of apertures are defined in the hydrophilic layer, wherein an orthogonal projection of each of the plurality of hollow grooves on the base substrate is within an orthogonal projection of the corresponding aperture on the base substrate.

5. The display panel according to claim 4, wherein the hydrophilic layer comprises a first portion covering the sidewalls of the plurality of apertures and a second portion covering the side, facing away from the base substrate, of the isolation portion.

6. The display panel according to claim 5, wherein a shape of an orthogonal projection of the first portion on the base substrate is an annulus, and an inner boundary of the annulus is coincident with a boundary of the orthogonal projection of each of the plurality of hollow grooves on the base substrate.

7. The display panel according to claim 1, wherein a refractive index of the hydrophobic layer is less than a refractive index of the light conversion structure.

8. The display panel according to claim 1, wherein the package layer comprises a first inorganic package layer, an organic package layer, and a second inorganic package layer that are laminated in a direction perpendicular to and away from the base substrate, wherein the hydrophobic layer is in direct contact with the second inorganic package layer, and a thickness of the hydrophobic layer is less than a thickness of the second inorganic package layer.

9. The display panel according to claim 1, wherein the plurality of light-emitting devices are configured to emit blue light, and the display panel comprises a red pixel sub-region, a green pixel sub-region, and a blue pixel sub-region; wherein
particles in the light conversion structure in the red pixel sub-region comprise red quantum dots for converting blue light to red light and scattering particles for scattering light;
particles in the light conversion structure in the green pixel sub-region comprise green quantum dots for converting blue light to green light and scattering particles for scattering light; and
particles in the light conversion structure in the blue pixel sub-region comprise scattering particles for scattering light.

10. The display panel according to claim 9, further comprising: an auxiliary package layer on a side, facing away from the base substrate, of the light conversion structure and a color resist layer on a side, facing away from the base substrate, of the auxiliary package layer, wherein the color resist layer comprises a red color resist block in the red pixel sub-region, a green color resist block in the green pixel sub-region, a blue color resist block in the blue pixel sub-region, and a black matrix between two adjacent color resist blocks.

11. A display device, comprising: a power supply assembly and a display panel electrically connected to the power supply assembly, wherein the display panel comprises: a base substrate, a plurality of light-emitting devices, a package layer, a hydrophobic layer, an isolation portion, and a light conversion structure; wherein
the plurality of light-emitting devices are disposed on a side of the base substrate;
the package layer is disposed on a side, facing away from the base substrate, of the plurality of light-emitting devices, and the package layer is configured to package the plurality of light-emitting devices;
the hydrophobic layer is disposed on a side, facing away from the base substrate, of the package layer, and the hydrophobic layer is in direct contact with the package layer;
the isolation portion is disposed on a side, facing away from the base substrate, of the hydrophobic layer, wherein a plurality of apertures in one-to-one correspondence to the plurality of light-emitting devices are defined in the isolation portion, and an orthogonal projection of each of the plurality of apertures on the base substrate covers an orthogonal projection of the corresponding light-emitting device on the base substrate; and
the light conversion structure is disposed in the plurality of apertures, and the light conversion structure comprises a transparent medium layer made of a hydrophobic material and a plurality of particles dispersed in the transparent medium layer, and a face, close to the base substrate, of the transparent medium layer is in direct contact with the hydrophobic layer.

12. A method for manufacturing a display panel, comprising:
forming a plurality of light-emitting devices on a side of a base substrate;
forming a package layer on a side, facing away from the base substrate, of the plurality of light-emitting devices, wherein the package layer is configured to package the plurality of light-emitting devices;
forming a hydrophobic layer on a side, facing away from the base substrate, of the package layer, wherein the hydrophobic layer is in direct contact with the package layer;
forming an isolation portion on a side, facing away from the base substrate, of the hydrophobic layer, wherein a plurality of apertures in one-to-one correspondence to the plurality of light-emitting devices are defined in the isolation portion, wherein an orthogonal projection of each of the plurality of apertures on the base substrate covers an orthogonal projection of the corresponding light-emitting device on the base substrate; and
forming a light conversion structure in the plurality of apertures, wherein the light conversion structure comprises a transparent medium layer made of a hydrophobic material and a plurality of particles dispersed in the transparent medium layer, and a face, close to the base substrate, of the transparent medium layer is in direct contact with the hydrophobic layer.

13. The method according to claim 12, wherein prior to forming the light conversion structure in the plurality of apertures, the method further comprises:
forming a hydrophilic layer on a side, facing away from the base substrate, of the isolation portion, wherein at least part of the hydrophilic layer is disposed on sidewalls of the plurality of apertures, and a plurality of hollow grooves in one-to-one correspondence to the plurality of apertures are defined in the hydrophilic layer, wherein an orthogonal projection of each of the plurality of hollow grooves on the base substrate is within an orthogonal projection of the corresponding aperture on the base substrate.

14. The method according to claim 12, wherein upon forming the light conversion structure in the plurality of apertures, the method further comprises:
forming an auxiliary package layer on a side, facing away from the base substrate, of the light conversion structure; and
forming a color resist layer on a side, facing away from the base substrate, of the auxiliary package layer.

15. The method according to claim 12, wherein forming the light conversion structure in the plurality of apertures comprises:
acquiring a mixed solution by mixing particles in a transparent solution made of the hydrophobic material; and
acquiring the light conversion structure by printing the mixed solution in the plurality of apertures by an inkjet printing process and curing the mixed solution in the plurality of apertures.

16. The display device according to claim 11, wherein the hydrophobic layer is made of an organic material.

17. The display device according to claim 16, wherein the hydrophobic layer comprises a hydrophobic layer body made of the organic material and a plurality of hollow particles dispersed in the hydrophobic layer body.

18. The display device according to claim 11, wherein the display device further comprising: a hydrophilic layer on a side, facing away from the base substrate, of the isolation portion, wherein at least part of the hydrophilic layer is disposed on sidewalls of the plurality of apertures, and a plurality of hollow grooves in one-to-one correspondence to the plurality of apertures are defined in the hydrophilic layer, wherein an orthogonal projection of each of the plurality of hollow grooves on the base substrate is within an orthogonal projection of the corresponding aperture on the base substrate.

19. The display device according to claim 18, wherein the hydrophilic layer comprises a first portion covering the sidewalls of the plurality of apertures and a second portion covering the side, facing away from the base substrate, of the isolation portion.

20. The display device according to claim 19, wherein a shape of an orthogonal projection of the first portion on the base substrate is an annulus, and an inner boundary of the annulus is coincident with a boundary of the orthogonal projection of each of the plurality of hollow grooves on the base substrate.
